(19) United States
(12) Patent Application Publication
(10) Pub. No.: US 2026/0246423 A1
(43) Pub. Date: Aug. 20, 2026

(54) ENHANCED CONVECTION FOR HIGHER MODULE AND SYSTEM EFFICIENCY

(71) Applicants: Portland State University, Portland, OR (US); University of Utah, Salt Lake City, UT (US); Institut Polytechnique de Grenoble, Grenoble (FR); Centre National de la Recherche Scientifique, Paris (FR); Université Grenoble Alpes, Saint Martin D'Hères (FR)

(72) Inventors: Raúl Bayoán Cal Santiago, Portland, OR (US); Sarah Elizabeth Smith, Portland, OR (US); Marc Calaf Bracons, Salt Lake City, UT (US); Martín Obligado, Villeneuve-d'Ascq (FR); Henda Djeridi, Grenoble (FR)

(73) Assignees: Portland State University, Portland, OR (US); University of Utah, Salt Lake City, UT (US); Institut Polytechnique de Grenoble, Grenoble (FR); Centre National de la Recherche Scientifique, Paris (FR); Université Grenoble Alpes, Saint Martin D'Hères (FR)

(21) Appl. No.: 19/164,182

(22) PCT Filed: Mar. 8, 2024
(86) PCT No.: PCT/US2024/019098

§ 371 Date: Sep. 10, 2025

Related U.S. Application Data
(60) Provisional application No. 63/489,698, filed on Mar. 10, 2023.

(51) Int. Cl. H02S 40/42

(52) U.S. Cl. CPC H02S 40/425

(57) ABSTRACT

A PV module cooling assembly can include vortex generators and upper and lower flow deflectors to improve surface convective cooling for a PV module. The vortex generators can include one or more winglets attached along an upstream edge portion of the PV module, locally modifying airflow at a front PV module surface by inducing turbulence from the oncoming flow and increasing local convective heat transfer. The upper and lower flow deflectors can capture and re-direct high-velocity flow to otherwise blocked regions known to recirculate heated air. The PV module cooling assembly is capable of improving surface cooling more than 50% compared to PV modules without flow alteration.

### CROSS-REFERENCE TO RELATED APPLICATION

This application claims the benefit of U.S. Provisional Patent Application No. 63/489,698, filed Mar. 10, 2023, which is incorporated by reference herein.

### ACKNOWLEDGMENT OF GOVERNMENT SUPPORT

This invention was made with government support under DOE DE-EE0008168 awarded by the United States Department of Energy. The government has certain rights in the invention.

### FIELD

The present disclosure relates to vortex generation and flow diversion systems for solar panels.

### BACKGROUND

Adverse heating as observed in solar photovoltaic (PV) plants leads to undesired power losses, accelerated degradation rates, and efficiency losses. The rate of PV module efficiency decreases per degree of temperature rise, where the efficiency of a silicon cell drops by about 0.5% with the increase of every one degree Celsius, and PV modules (which are also referred to herein as “solar panels,” “solar modules,” and/or “panels”) in real atmospheric conditions can typically operate at 25° C. above ambient temperature or above. Accordingly, a need exists for improved systems and methods for cooling PV modules.

### SUMMARY

The present disclosure relates to apparatuses, systems and methods pertaining to a PV module with vortex generation and flow deflection components configured to reduce the operating temperature of the PV module.

In some examples, a PV module cooling assembly can comprise a PV module and at least one vortex generator. The PV module can comprise a front PV module surface, a back PV module surface opposite the front PV module surface, a lower edge portion, and an upper edge portion disposed in a downstream direction relative to the lower edge portion. The least one vortex generator can be coupled to the lower edge portion of the PV module.

In some examples, the at least one vortex generator can comprise a trapezoidal winglet.

In some examples, the at least one vortex generator can be mounted to the PV module at an angle relative to a streamwise direction.

In some examples, a PV module cooling assembly can comprise a PV module. The PV module may comprise a front PV module surface, a back PV module surface opposite the front PV module surface, a lower edge portion, and an upper edge portion disposed in a downstream direction relative to the lower edge portion.

In some examples, the PV module cooling assembly can further comprise a vortex generator strip coupled to the lower edge portion of the PV module, the vortex generator strip comprising a plurality of vortex generators.

In some examples, the PV module cooling assembly can further comprise a lower flow deflector coupled to the lower edge portion of the PV module, wherein the lower flow deflector can be configured to re-direct windflow across the back PV module surface.

In some examples, the PV module cooling assembly can further comprise an upper flow deflector coupled to the upper edge portion of the PV module.

In some examples, the lower flow deflector can be curved.

In some examples, the upper flow deflector can have a curved profile.

In some examples, a PV module cooling assembly can comprise a first PV module and a first lower flow deflector coupled to a first lower edge portion of the first PV module. The PV module cooling assembly can further comprise a second PV module and a second lower flow deflector coupled to a second lower edge portion of the second PV module. The second PV module can be disposed in a downstream direction relative to the first PV module. The second lower flow deflector can extend further downward below the second lower edge portion of the second PV module than the first lower flow deflector extends below the first lower edge portion of the first PV module.

The foregoing and other objects, features, and advantages will become more apparent from the following detailed description, which proceeds with reference to the accompanying figures.

### BRIEF DESCRIPTION OF THE DRAWINGS

FIG. 1 is a perspective view of a PV module cooling assembly comprising vortex generation and flow diversion features coupled to a PV module, according to one example.

FIG. 2 is a perspective view of a vortex generator strip of the PV module cooling assembly of FIG. 1.

FIG. 3 is a top-down view of a modified vortex generator strip.

FIG. 4 comprises a perspective view and several magnified views of the PV module cooling assembly in order to illustrate vortex generator strip dimensions.

FIGS. 5A-5C are perspective views of example models for computational fluid dynamics simulations involving various PV module cooling assembly configurations.

FIG. 6 is a table describing different configurations of PV module cooling assemblies subject to computational fluid dynamics simulations.

FIGS. 7A-7B are graphs illustrating the results of computational fluid dynamics simulations involving various PV module cooling assembly configurations.

FIGS. 8A, 8B and 8C illustrate a wind tunnel facility and a subject under experiment, according to one example.

FIG. 9 is a chart summarizing results from wind tunnel experiments using the wind tunnel facility.

### DETAILED DESCRIPTION

### General Considerations

For purposes of this description, certain aspects, advantages, and novel features of the embodiments of this disclosure are described herein. The disclosed methods, apparatus, and systems are not limiting in any way. Instead, the present disclosure is directed toward all novel features and aspects of the various disclosed embodiments, alone and in various combinations and sub-combinations with one another. The methods, apparatus, and systems are not limited to any specific aspect or feature or combination thereof, nor do the disclosed embodiments require that any one or more specific advantages be present, or problems be solved. The scope of this disclosure includes any features disclosed herein combined with any other features disclosed herein, unless physically impossible.

Although the operations of some of the disclosed embodiments are described in a particular, sequential order for convenient presentation, it should be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed components can be used in conjunction with other components.

As used in this disclosure and in the claims, the singular forms “a,” “an,” and “the” include the plural forms unless the context clearly dictates otherwise. Additionally, the term “includes” means “comprises.” Further, the terms “coupled” and “associated” generally mean electrically, electromagnetically, and/or physically (e.g., mechanically or chemically) coupled or linked and does not exclude the presence of intermediate elements between the coupled or associated items absent specific contrary language.

In some examples, values, procedures, or apparatus may be referred to as “lowest,” “best,” “minimum,” or the like. Such descriptions are intended to indicate that a selection among many alternatives can be made, and such selections need not be better, smaller, or otherwise preferable to other selections.

In the description, certain terms may be used such as “up,” “down,” “upper,” “lower,” “horizontal,” “vertical,” “left,” “right,” and the like. These terms are used, where applicable, to provide some clarity of description when dealing with relative relationships. But these terms are not intended to imply absolute relationships, positions, and/or orientations. For example, with respect to an object, an “upper” surface can become a “lower” surface simply by turning the object over. Nevertheless, it is still the same object.

Unless otherwise indicated, all numbers expressing dimensions, forces, masses, frequencies, material quantities, angles, pressures, molecular weights, percentages, temperatures, times, and so forth, as used in the specification or claims are to be understood as being modified by the term “about.” Accordingly, unless otherwise indicated, implicitly or explicitly, the numerical parameters set forth are approximations that can depend on the desired properties sought and/or limits of detection under test conditions/methods familiar to those of ordinary skill in the art. When directly and explicitly distinguishing embodiments from discussed prior art, the embodiment numbers are not approximations unless the word “about” is recited. Furthermore, not all alternatives recited herein are equivalents.

Although there are alternatives for various components, parameters, operating conditions, etc., set forth herein, that does not mean that those alternatives are necessarily equivalent and/or perform equally well. Nor does it mean that the alternatives are listed in a preferred order unless stated otherwise.

### Overview of the Disclosed Technology

In certain examples, structures that facilitate increased surface convective cooling can help mitigate the adverse heating of PV modules. For example, turbulent coherent structures can be an efficient means of transporting heat, moisture, momentum, and energy. For this reason, structures that promote the development of coherent turbulent eddies (which are also referred to herein as “coherent turbulent structures”) on the surface of the PV modules through the incorporation of module vortex generators can lead to dissipation enhancement. For example, the existence of coherent turbulent eddies induced by micro-vortex generators can enhance heat transfer by even more than 100% in thermal systems such as heat exchangers. Within wind farms, coherent turbulent eddies can enhance mixing and entrainment of mean kinetic energy by 50%, a result that is crucial for the recovery of the wakes of wind turbines and hence the economical viability of large wind farms. Coherent turbulent eddies are vortices that regularly form in naturally and artificially induced shear flows. Coherent turbulent eddies tend to be long-lived, traveling for extended periods of time (and long distances) before being dissipated. These coherent turbulent eddies can be generated with vortex generators.

Ultimately, promoting the development of coherent turbulent eddies on the surface of the PV modules can provide more than a 5% gain in the efficiency of the PV modules by passively manipulating the external airflow and increasing the convective heat transfer coefficient h. For example, consider a first case where the PV module has a 335W rated power with an efficiency of 15% at 25° C. and operates at an equilibrium temperature of ~64° C. (given a fixed h=14W/(m²K)) and a contrasting second case where the PV module would be operating at a cooler temperature closer to ambient values, such as for example T−T_{∞}≈14° C. (with T_{∞}=25° C. being the ambient temperature and T, the PV module operating temperature). In the second case, energy harvesting efficiency would increase by 12%. However, to be able to decrease the operating temperature by the above ~25° C., heat dissipation (directly related to h) should have a 2.75-fold (175%) increase.

Within this project we originally estimated being able to at least increase the convective heat transfer coefficient by 40%, and hence increase the annual energy yield by at least 5%. This increase in the convective heat transfer coefficient would reduce the PV module operating temperature close to ambient temperature, such that 10° C.≤T−T_{∞}≤30° C. This reduction of the PV module's operating temperature is also estimated to decrease the PV module degradation by +0.3%/year, reducing the overall LCOE by 2.9-4.5¢/kWh. The enhanced thermal diffusivity (or cooling) required to provide this increase in harvested power is shown here to be achievable by promoting strong turbulent transport/mixing at the PV module surfaces.

Vortex generation and flow diversion systems employed in small-scale internal cooling systems, such as in electronics packaging, usually interact with forced air constrained in small channels where the newly turbulent flow is forced to interact closely with the surfaces. When applied to external flows, as in wind energy and aerospace applications, the aim of vortex generation is to prolong boundary layer interaction for aid in physical lift and drag on airfoil-type surfaces. However, the specific subject of vortex-generated heat transfer on surfaces in external environments is an undefined study, especially in terms of low-velocity flow within the canopylike geometries of large-scale solar farms. In current industrial applications, vortex generator (“VG”) geometry, orientation, and location can vary significantly with respect to the expected function. In the high-velocity and external flows associated with aviation, for example, the vortex generator shape and placement are optimized to maintain fluid-wing boundary layer contact on aircraft wings and differ from those designed for smaller channel flows such as computer heat-sinks.

Implementing large-scale cooling within the low-velocity, external flows typical of PV plants is extremely new territory and the potential best practices for VG configuration, shape, and placement are not yet defined. These features are numerous, considering that for a commonly used vortex generator, parameters such as inclination (e.g., α), height (e.g., h), length (e.g., L), spacing (e.g., S₁, S₂, S₃), and attack angle (e.g., β) can be infinitely varied. The vortex generators presented here have been tested with commercial CFD software and studied experimentally in wind tunnel tests finding significant improvement between 20% and 50% in average PV module cooling when mounted.

### Examples of the Disclosed Technology

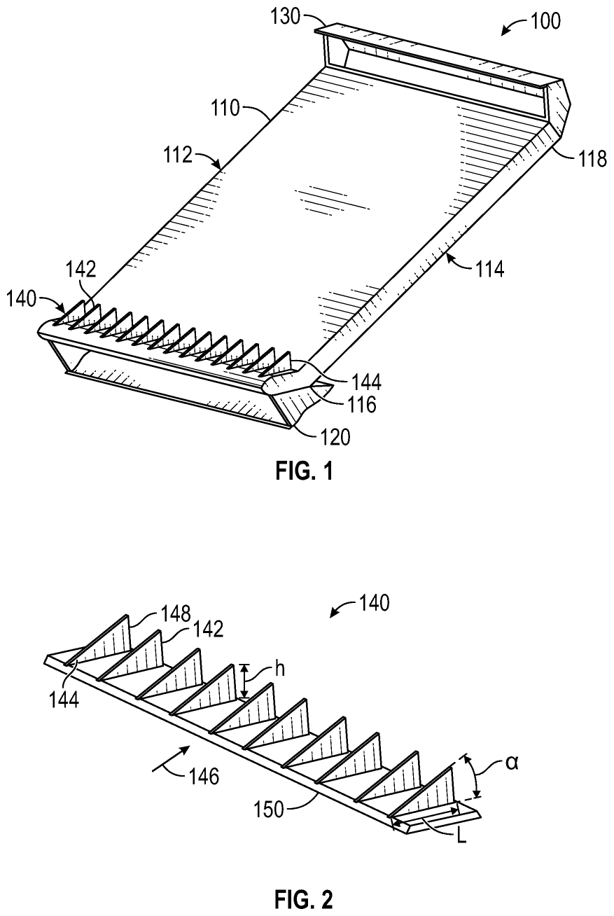

FIG. 1 is a perspective view of a PV module cooling assembly 100 (which is also referred to herein as a “solar panel cooling assembly,” “panel cooling assembly,” “solar module cooling assembly,” etc.) comprising vortex generation and flow diversion features coupled to a PV module 110, according to one example. The PV module cooling assembly 100 comprises the PV module 110 having a front PV module surface 112 (which is also referred to herein as a “front solar panel surface” and/or a “front panel surface”) and a back PV module surface 114 (which is also referred to herein as a “back solar panel surface” and/or a “back panel surface”) opposite the front PV module surface 112. The front PV module surface 112 is configured to generally face towards a solar energy source (for example, in an upwards direction towards the sun).

The vortex generation and flow diversion features coupled to the PV module 110 can comprise a lower flow deflector 120 (which is also referred to herein as a “LFD,” a “front flow deflection device,” and/or a “front flow deflector”), an upper flow deflector 130 (which is also referred to herein as a “UFD,” a “rear flow deflection device,” and/or an “upper flow deflector”), and a vortex generator strip 140 (which is also referred to herein as a “vortex generator plate” and/or a “vortex generator”).

The lower flow deflector 120 is coupled to a lower or forward edge portion 116 of the PV module 110. In some examples, the lower flow deflector 120 can extend a portion or an entirety of the width of the lower edge portion 116 of the PV module 110. The upper flow deflector 130 is coupled to an upper or rear edge portion 118 of the PV module 110. The upper or rear edge portion 118 is disposed downstream (for example, further along in a direction of airflow across the PV module 110) relative to the lower or forward edge portion 116. In some examples, the upper flow deflector 130 can extend a portion or an entirety of the width of the upper edge portion 118 of the PV module 110.

The lower flow deflector 120 and the upper flow deflector 130 are configured to re-direct increased velocity winds which ramp off of the front PV module surface 112 into a previously wind-blocked region behind the PV module 110. The lower flow deflector 120 captures this high energy wind and propels it upward along the back PV module surface 114, forcing increased heat removing windflow along the back PV module surface 114. Together, the newly provoked, high-energy flow behind the PV module 110 eliminates recirculating heat formerly trapped in the panel wake, instead promoting cooling through turbulent mixing. Additionally, these results allow for new, high-energy flow to interact with subsequent PV modules downstream and carry heat away from the previously overheated front PV module surface 112.

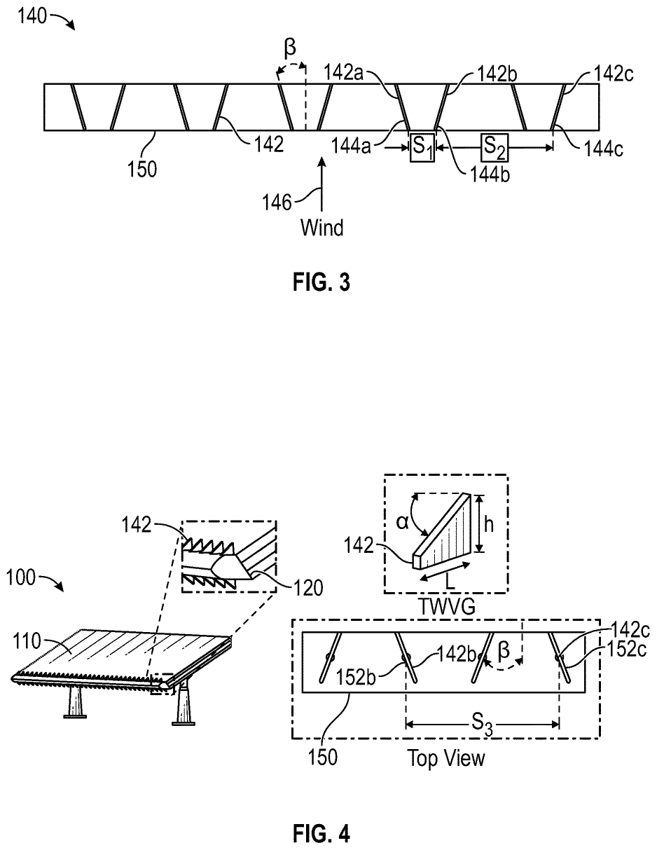

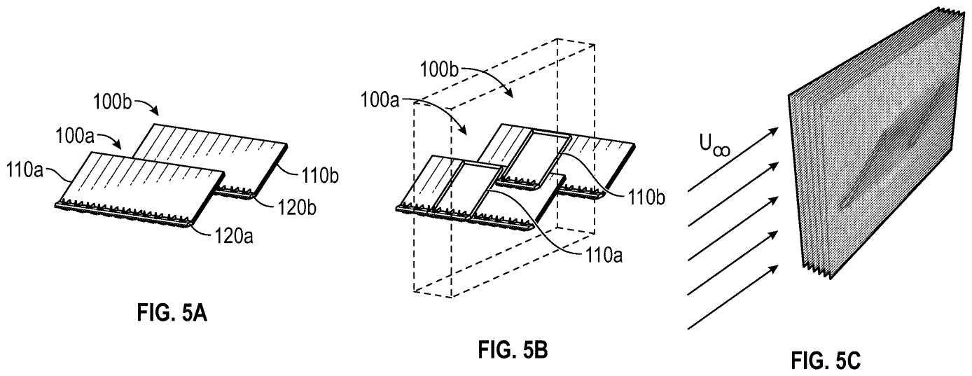

As shown in FIGS. 2-3, the vortex generator strip 140 can comprise a modular strip of one or more vortex generators 142 (which are also referred to herein as “trapezoidal winglet vortex generators” and/or “TWVGs”) whose profiles can be sized and shaped as trapezoidal winglets. However, it should be understood that other embodiments of the vortex generators 142 can have non-trapezoidal profiles, including but not limited to triangular profiles, hemispherical profiles, semielliptical profiles, square profiles, polygonal profiles, etc. Similar to airfoil vortex generators, the vortex generators 142 shown in FIG. 2 have upwardly slanting profiles in a streamwise direction (as indicated by arrow 146). For example, a frontal, upstream portion 144 of one of the vortex generators 142 is lowest (for example, relatively closest to the front PV module surface 112), and a rear, downstream portion 148 of the vortex generator 142 is highest (for example, relatively furthest to the front PV module surface 112). The profile of the vortex generators 142 can be inclined angles of α=15°, 20°, and 25°, with rear heights of either h=1/22Lₚ or 1/55Lₚ, where Lₚ is the length in the streamwise direction of the surface geometry of the PV module 110 from which the heat is leaving. The vortex generators 142 can have a length L as shown. However, it should be understood that the vortex generators 142 can have any other profile. For example, the profile of the vortex generators 142 can be inclined at angles (α) other than the previously described increments and can have magnitudes less than 15° or greater than 25°. Furthermore, the height (h) can be any fraction or multiple of Lₚ. In some examples, the vortex generator strip 140 can comprise a plurality of vortex generators 142, wherein the plurality of vortex generators 142 have a plurality of different profiles.

In the illustrated example, the vortex generator strip 140 comprises ten vortex generators 142. The vortex generators 142 are arranged in pairs. However, it should be understood that the vortex generator strip 140 can comprise one, two, three, four, five, six, seven, eight, nine, eleven, twelve, thirteen, fourteen, or any other number of vortex generators 142. Furthermore, it should be understood that the vortex generators 142 need not be arranged in pairs and can be arranged in any configuration, either individually or in a group of any number of other vortex generators 142.

In the illustrated example, the vortex generators 142 are mounted to a plate 150, wherein the plate 150 is configured to be coupled to the PV module 110. However, in other examples, the vortex generators 142 may be coupled or mounted directly to the PV module 110 or to the lower flow deflector 120. As shown in FIG. 3, the vortex generators 142 can be mounted to the plate 150 or to the PV module 110 at an angle (β) relative to the streamwise direction (indicated by arrow 146). As also shown in FIG. 3, the vortex generators 142 can be set in pairs, rotated in a horizontal plane (for example, a plane parallel to the front PV module surface 112) at angles of β=0, 15, and 20 degrees. In a pair comprising a first vortex generator 142a and a second vortex generator 142b, the two vortex generators 142a, 142b can be mounted at the same angle (β) or different angles (β). However, it should be understood that the vortex generators 142 can be mounted at angles (β) between the angles of 0, 15 and 20 degrees and/or angles (β) with magnitudes greater than 20 degrees.

In the pair comprising the first vortex generator 142a and the second vortex generator 142b, a first upstream portion 144a of the first vortex generator 142a can be disposed at a first separation distance (S₁) from a second upstream portion 144b of the second vortex generator 142b, wherein the first separation distance (S₁) is perpendicular to the streamwise direction. The second upstream portion 144b of the second vortex generator 142b can be disposed at a second separation distance (S₂) from a third upstream portion 144c of a third vortex generator 142c belonging to an adjacent pair of vortex generators 142, wherein the second vortex generator 142b and the third vortex generator 142c are similarly angled relative to the streamwise direction (indicated by arrow 146). The second separation distance (S₂) is perpendicular to the streamwise direction.

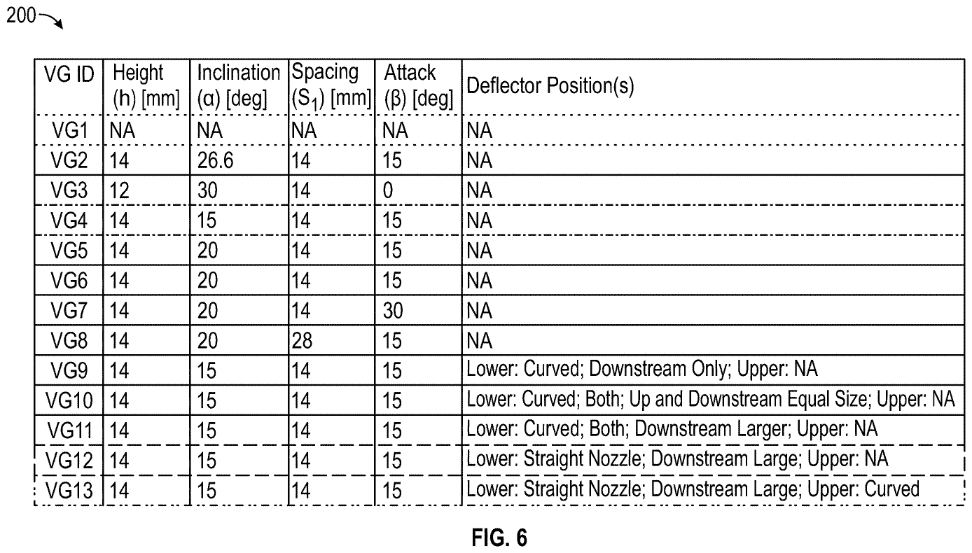

FIG. 4 comprises a perspective view of the PV module cooling assembly 100 and magnified images of the vortex generator strip 140 and the vortex generator 142 in order to better illustrate vortex generator geometry. In particular, FIG. 4 shows a portion of the vortex generator strip 140 comprising two pairs of vortex generators 142. A second intermediate portion 152b of the second vortex generator 142b can be disposed at a spacing (S₃) (which is also referred to herein as a “VG pair spacing” a “VG spacing,” and/or a “third separation distance”) from a third intermediate portion 152c of the third vortex generator 142c belonging to the adjacent pair of vortex generators 142, wherein the second vortex generator 142b and the third vortex generator 142c are similarly angled relative to the streamwise direction. The spacing (S₃) is perpendicular to the streamwise direction.

### Design Validation

Validation of vortex generator (VG) geometry and placement was first performed with simulations using computational fluid dynamics (CFD) software, and subsequently tested experimentally for key configurations. The vortex generator geometry, including the shape, angle of attack (β), angle of incline (α) and length (L) parameters can affect vorticity strength and longevity, altering convective cooling at the surface. The left half of FIG. 4 is a diagram representing placement and key geometric features for the PV module cooling assembly 100, and the right half of FIG. 4 demonstrates how these parameters are defined for the trapezoidal winglet vortex generators 142 (TWVG), with h as relative height and S₃ as VG pair spacing.

### Computational Fluid Dynamics Simulations

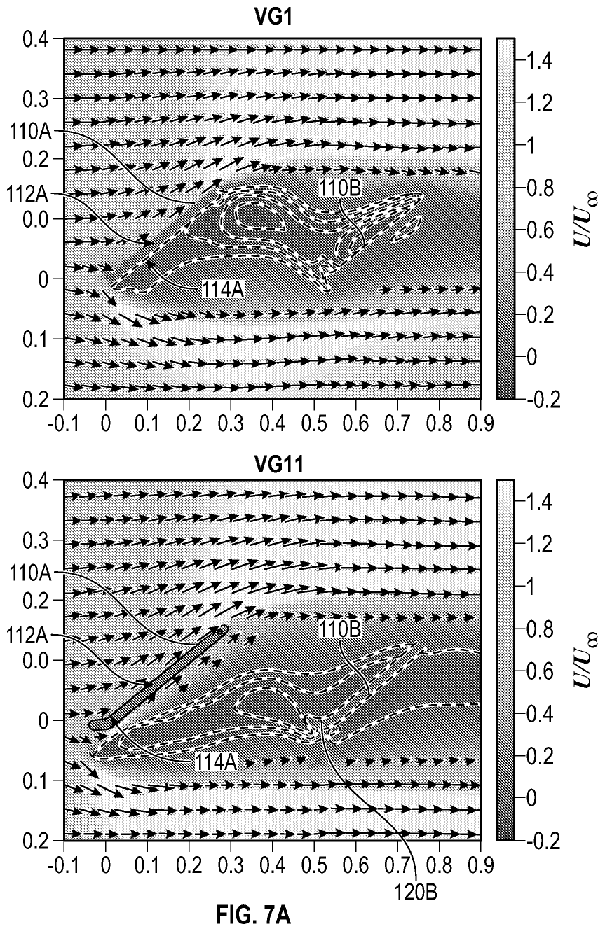

Initial validation consisted of simulations were performed in StarCCM+, an academically licensed commercial computational fluid dynamics (CFD) software. Results from this study allowed direct observation of the flow behavior contributing to panel heat shedding and its dependence on interaction with the panels and vortex generators. As seen in FIGS. 5A-5C, each CFD simulation comprises models of at least two PV module cooling assemblies 100a, 100b arranged in the streamwise direction. Each PV module cooling assembly 100a, 100b comprises a respective PV module 110a, 110b. Although only two PV modules 110a, 110b are shown in FIG. 5, it should be understood that some CFD simulations comprised more than two PV modules 110.

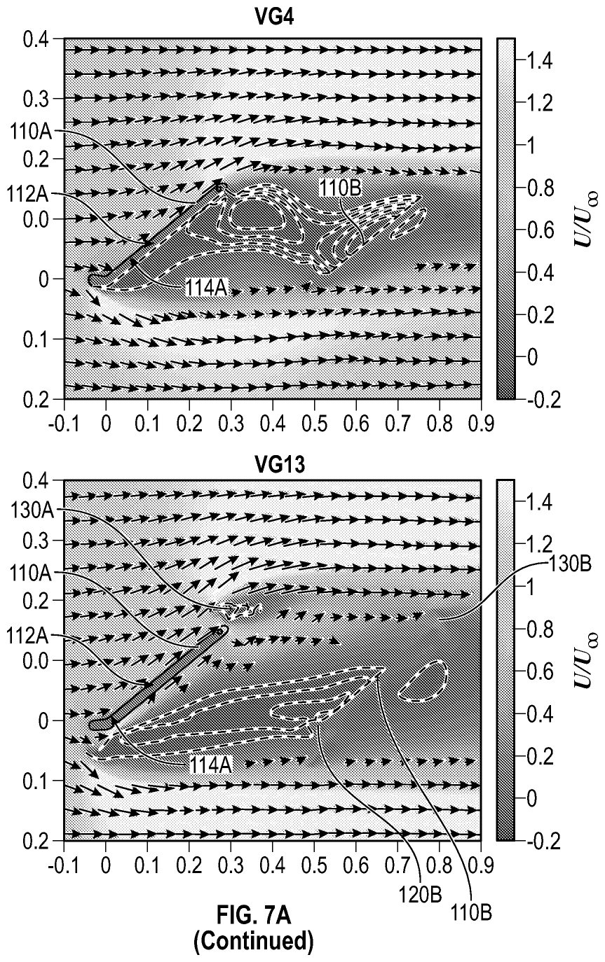

FIG. 6 is a table 200 defining thirteen PV module cooling assembly configurations validated using CFD simulations. The configurations are labelled “VG1” through “VG13.” The table 200 lists the inclination angle (α), VG length (L), VG height (h), and VG spacing (S₁) of the different VG configurations. Configuration VG1, outlined in black, represents the PV modules 110a, 110b alone without vortex generator strips 140, front flow deflectors 120, or rear flow deflectors 130 applied. The nominal configuration of VG4, comprising the PV module 110 and the vortex generator strip 140, is highlighted in blue, with a height of h=1/22Lₚ=14 mm, inclination α=15°, VG pair spacing of S₁=h, angle of attack of β=15°, and no other additional flow deflectors 120, 130 attached to the PV module 110. Configurations VG1 through VG8 represent changes to the geometry of the vortex generator strips 140, while VG9 to VG13 vary with application and positioning of attached lower and upper flow deflectors 120, 130. As reference, the deflector design shown in FIG. 1 represents the VG13 configuration, with the straight-profile lower flow deflector (LFD) 120 coupled to the lower edge portion 116 of the PV module 110, and the curved-profile upper flow deflector (UFD) 130 coupled to the upper edge portion 118 of the PV module 110 to pull faster moving air into the array. In cases VG9 through VG12, the PV module cooling assemblies 100 are equipped with only lower flow deflectors 120 and vortex generator strips 140 (i.e., no upper flow deflectors 130). In addition to vortex generator strips 140 on each PV module cooling assembly 100, the downstream PV module 110b in VG9 is equipped with a curved LFD. Case VG10 incorporates curved LFDs of equal size coupled to all upstream PV modules 110a and downstream PV modules 110b. In VG11 to VG13, downstream LFDs 120b are extended further downward below the lower edge portion 116 than LFDs 120a the upstream PV modules 110a in order to capture faster moving, sub-panel flow. VG13 utilizes UFDs 130 for all PV modules 110 as shown in FIG. 1.

Analyses in these simulations were identical for all geometric cases, based on K-Epsilon turbulence and solved through the Reynolds-averaged Navier-Stokes equations with steady state assumptions. The interrogation regions for each simulation encompass a minimum of two PV modules (for example, PV modules 110a, 110b), with inflow oriented at a first front PV module surface 112a of the first PV module 110a, to observe downstream effects on subsequent PV modules (such as PV module 110b) due to flow deflection. An example of the scaled VG4 three-dimensional (3D) model is shown in FIG. 5A. To maximize efficiency, the surrounding air volume is refined to a central subsection consisting of a minimum of three vortex generator pairs in all cases (FIG. 5B). The side walls are defined as symmetry boundaries, simplifying the problem to assume a repeated physical state beyond the walls. The inlet boundary is set to impose a constant inflow velocity of U_{∞}=5 ms⁻¹. PV module surfaces are defined with a constant heat flux of q=1050 Wm⁻² to represent simulated panel irradiance representative of slight overheating compared to standard test conditions (STC) (q=105%×qSTC). The air volume is then meshed with a base cell size of 3 mm, with surface refinement on the order of 1 mm and a maximum cell size of 3 cm in the largest open regions of the volume. A sliced representation of the meshed section is shown in FIG. 5C. Each simulation is run until residual errors for continuity equation, energy equation, and turbulence dissipation rate are on the order of 10⁻³.

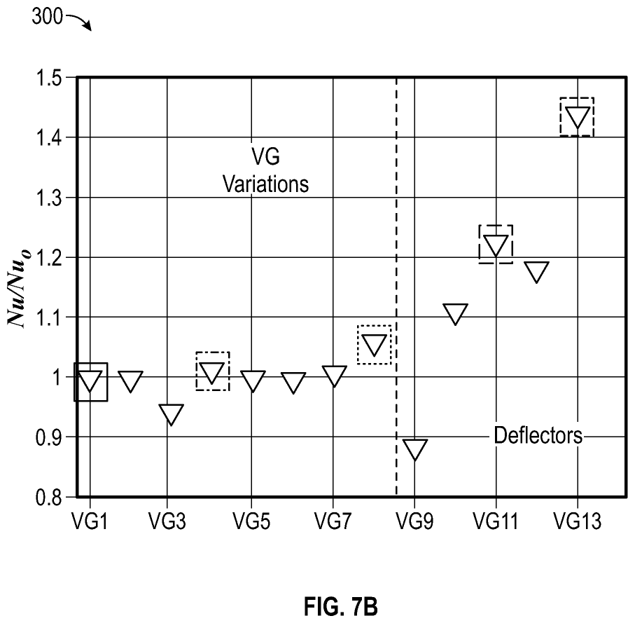

FIG. 7A contains mean velocity flow field results represented as contours, where the arrow size and direction represent velocity magnitude and trajectory. Contour colors are based on the spatially averaged streamwise velocity, moving from left to right, and normalized by the inflow velocity U_{∞}. Here, yellow indicates high-velocity flow in the direction of the inflow, while blue indicates slower (or sometimes reversed) velocities. The PV modules 110a, 110b are visible as no-velocity, slanted blue bars. The top-left contour represents the simple PV module VG1 configuration (i.e., no flow alteration), top-right the nominal VG4, bottom-left represents VG11 with lower flow deflection (for example, including lower flow deflector(s) 120), and bottom-right is the VG13 configuration as shown in FIG. 1. Black dotted lines in FIG. 7A outline regions of negative velocity, where the flow is recirculating within the PV module wakes. These recirculation zones tend to keep the warm air near to the heated PV modules 110a, 110b, lessening the ability for the faster flow to remove heat from the surfaces. Compared to VG1, the addition of vortex generator strips 140 in VG4 works to minimize the recirculation region, allowing higher-velocity flow to interact more with the downstream PV module 110b. By re-directing the flow with lower deflectors as for VG11, this recirculation is further diminished especially near the upstream PV module 110a, where the fast-moving air is guided along a rear surface 114a of the upstream PV module 110a. With the addition of upper flow deflectors 130a, 130b in VG13, the wind above the downstream solar PV module 110b is carried downward into the panel wake, further decreasing the recirculation region and exposing more of the downstream PV module's surface to potentially heat-removing windflow.

These effects are quantified in terms of heat transfer within FIG. 7B. FIG. 7B is a chart 300 showing an overall Nusselt number (Nu=hLₚ/k), as averaged over the upstream and downstream PV modules 110a, 110b, and normalized by that of the VG1 simulation case (Nu₀=Nu_{VG1}), for each of the simulation results. The Nusselt number describes how well heat is removed from a surface through the convective heat transfer coefficient h, calculated from the constant heat flux. The length parameter Lₚ generally represents the surface geometry from which the heat is leaving, and k is the thermal conductivity of the fluid. The colored boxes match configurations as outlined in FIG. 6. For example, the black box denotes VG1, the PV module 110 alone without flow alteration, and red represents VG13 with the lower and upper flow deflectors 120, 130. The dotted red line in 7B separates configurations where only vortex generator features (such as vortex generator strips 140) are varied (left side) from those also with flow deflection (such as lower and upper flow deflectors 120, 130) applied (right).

In terms of the VG variations considered, VG4 and VG8 show improvement over VG1 with an increase of approximately 2.5% and 7%, respectively. This is primarily due to a thinning of the recirculation region in the upstream panel wake, allowing for more high-velocity, heat-removing flow to interact with the second PV module 110b. The addition of flow deflection in VG11 and VG13 boast increases of over 20% and 40%, respectively, due to re-direction of flow along the rear of the PV module surfaces and even more pronounced thinning of the wake.

### Wind Tunnel Experiments

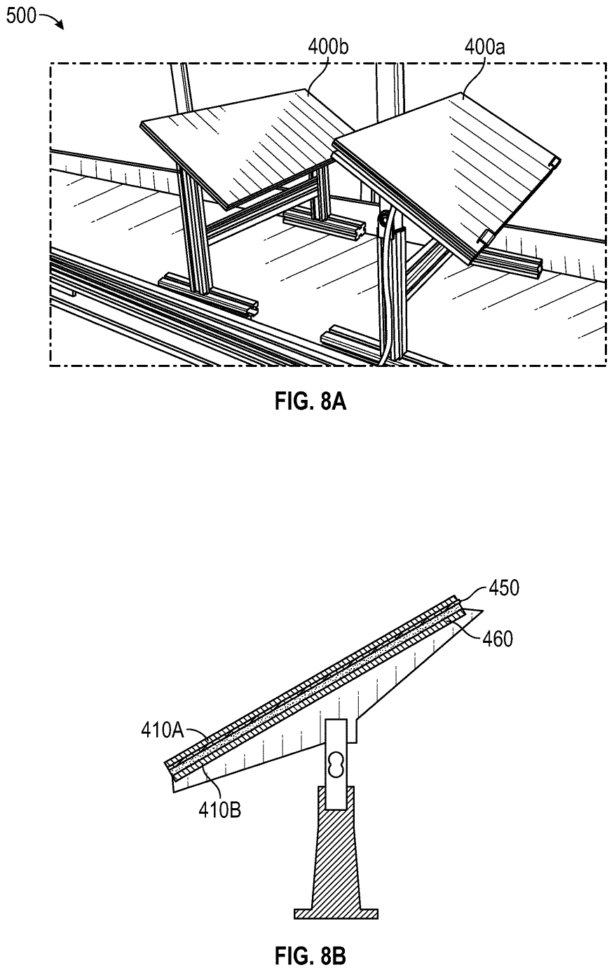

Key configurations from the simulation results were tested in wind tunnel experiments on PV module analogs 400a, 400b (which are also referred to herein as “module analogs”). FIG. 8A shows an example wind tunnel facility 500, wherein the facility used contains a closed-circuit wind tunnel with a cross-section of 0.75 by 0.75m² , and a test section length of 4 m. As shown in FIG. 8B, the PV module analogs 400a, 400b comprised two aluminum plates 410a, 410b, each approximately 63.5×30.5×0.6 cm³ and separated by kapton heaters 450 and aerogel insulation 460 between the panels, with a nominal inclination angle set at 30°. As shown in FIG. 8C, some PV module analogs further comprise vortex generator strips 440, which are similar to vortex generator strips 140.

Similar to the simulations, the PV module analogs 400a, 400b are heated to a constant heat flux to mimic component heating and solar irradiance imposed on the model PV modules. Both PV module analogs 400a, 400b are equipped with Type-T thermocouples embedded under upper and lower PV module analog surfaces to capture thermal behavior. Experimental parameters were chosen to represent environmental conditions known to affect PV convection. For example, the convective improvements due to varied wind speeds are of interest since vortex generation and the relative cooling possible are dependent on the flow velocities they are subjected to.

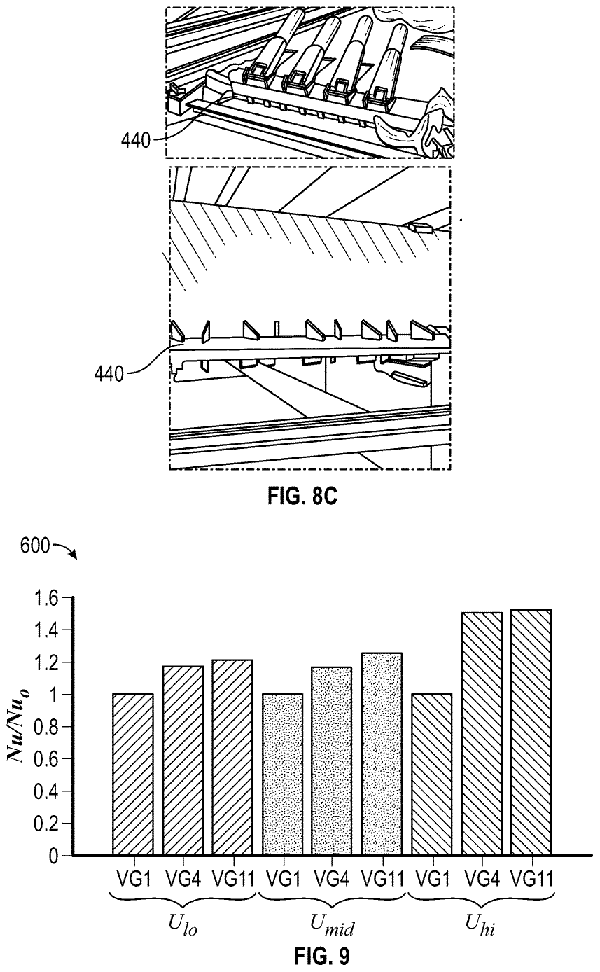

FIG. 9 is a chart 600 showing the averaged, normalized convective Nu (such as the normalized corrective Nu shown in FIG. 7B) for three of the discussed configurations tested in the wind tunnel facility 500 using the PV module analogs 400a, 400b, at three varied inflow velocities. The configurations are labeled the same as in FIGS. 6-7 and consider a case without flow alteration (VG1), a case with nominal vortex generator strips 440 on both PV module analogs 400a, 400b (VG4), a configuration with nominal vortex generator strips 440 and lower flow deflectors (similar to lower flow deflectors 120) on both PV module analogs 400a, 400b (VG11). The three velocities (Uₗₒ, U_{mid}, and Uₕᵢ), represent a range from 2.2 to 5.7 ms⁻¹, encompassing low-to-high average annual windflow velocities available around Phoenix, Arizona, USA. For each respective inflow velocity, Nu for each VG configuration is normalized by that of the no-flow-alteration case VG1.

As observed for all velocities in FIG. 9, imposed vortex generation and flow deflection on the PV module analogs 400a, 400b result in similar improvements as seen for the idealized CFD simulations. In the low and mid velocity cases, Uₗₒ=2.2 ms⁻¹ and U_{mid}=3.9 ms⁻¹, presence of VGs provokes an approximate 20% improvement in cooling for VG4 versus VG1 due to increased surface turbulence. The addition of lower flow deflectors with VG11 boosts this to nearly 25%. At the highest wind speed, Uₕᵢ=5.7 ms⁻¹, the convective benefits are most pronounced, as interaction of the high velocity winds further enhance turbulent boundary layer effects toward increases in convection of over 50% for both VG4 and VG11 compared to the no flow deflection case VG1.

### Additional Considerations

In view of the many possible embodiments to which the principles of the disclosure may be applied, it should be recognized that the illustrated embodiments are only examples and should not be taken as limiting the scope of the disclosure. Various modifications may be made thereto without departing from the broader spirit and scope of the disclosure as set forth. The specification and drawings are, accordingly, to be regarded in an illustrative sense rather than a restrictive sense. Accordingly, the scope of the disclosure is at least as broad as the full scope of the following exemplary claims and equivalents of the recited features.

1-6. (canceled)

7. A solar panel cooling assembly comprising:
a solar panel comprising a front surface, a back surface opposite the front surface, a lower edge portion, and an upper edge portion disposed in a downstream direction relative to the lower edge portion;
a vortex generator strip coupled to the lower edge portion of the solar panel, the vortex generator strip comprising a plurality of vortex generators; and
a lower flow deflector coupled to the lower edge portion of the solar panel, wherein the lower flow deflector is configured to re-direct windflow across the back surface of the solar panel; and
an upper flow deflector coupled to the upper edge portion of the solar panel, wherein the upper flow deflector is configured to redirect windflow ramping off the front surface of the solar panel into a region behind the back surface of the solar panel.

8. The solar panel cooling assembly of claim 7, wherein the lower flow deflector is curved.

9. The solar panel cooling assembly of claim 7, wherein the upper flow deflector has a curved profile.

10. The solar panel cooling assembly of claim 7, wherein the plurality of vortex generators are arranged in pairs of vortex generators, and wherein each pair of vortex generators comprises a first vortex generator and a second vortex generator.

11. The solar panel cooling assembly of claim 10, wherein at least one of the first vortex generator and the second vortex generator is set at an angle relative to a streamwise direction.

12. The solar panel cooling assembly of claim 11, wherein at least one of the first vortex generator and the second vortex generator is set at a 15 degree angle relative to the streamwise direction.

13. The solar panel cooling assembly of claim 11, wherein the first vortex generator and the second vortex generator are set at the same angle relative to the streamwise direction.

14. The solar panel cooling assembly of claim 7, wherein the vortex generator strip further comprises a plate, and wherein each one of the plurality of vortex generators are mounted to the plate.

15. A solar module cooling assembly comprising:
a first solar module and a first lower flow deflector coupled to a first lower edge portion of the first solar module; and
a second solar module and a second lower flow deflector coupled to a second lower edge portion of the second solar module,
wherein the second solar module is disposed in a downstream direction relative to the first solar module; and
wherein the second lower flow deflector extends further downward below the second lower edge portion of the second solar module than the first lower flow deflector extends below the first lower edge portion of the first solar module.

16. The solar module cooling assembly of claim 15, further comprising a first vortex generator strip coupled to the first lower edge portion of the first solar module, wherein the first vortex generator strip comprises a plurality of vortex generators.

17. The solar module cooling assembly of claim 16, wherein each one of the plurality of vortex generators has an upwardly slanting profile in a streamwise direction, and wherein the upwardly slanting profile of each one of the plurality of vortex generators is inclined at an angle of 15 degrees.

18. The solar module cooling assembly of claim 16, wherein each one of the plurality of vortex generators is set at an angle of 15 degrees relative to a streamwise direction.

19. The solar module cooling assembly of claim 16, wherein the plurality of vortex generators are set in pairs.

20. The solar module cooling assembly of claim 16, further comprising a second vortex generator strip coupled to the second lower edge portion of the second solar module.
